(19) United States
(12) Patent Application Publication
(10) Pub. No.: US 2009/0065056 A1
(43) Pub. Date: Mar. 12, 2009

(54) HYBRID PHOTOVOLTAICALLY ACTIVE LAYER AND METHOD FOR FORMING SUCH A LAYER

(75) Inventors: Deepak Upadhayaya, Fremont, CA (US); William J. Boardman, Danville, CA (US); Charles Dornfest, Fremont, CA (US)

Correspondence Address: SCHNECK & SCHNECK, P.O. BOX 2-E, SAN JOSE, CA, 95109-0005, US

(73) Assignee: Sub-One Technology, Pleasanton, CA (US)

(21) Appl. No.: 12/209,362

(22) Filed: Sep. 12, 2008

Related U.S. Application Data
(60) Provisional application No. 60/993,567, filed on Sep. 12, 2007.

(51) Int. Cl. H01L 31/00; B01J 19/08

(52) U.S. Cl. 136/261; 427/578

(57) ABSTRACT

A “hybrid” photovoltaically active layer is homogenous (in a direction parallel to the major surfaces of the layer) with respect to film constituents, but is non-homogenous with respect to photovoltaic properties. First regions exhibit high absorptivity, while second regions that are perpendicular to the major surfaces of the layer exhibit a higher carrier mobility. The method for forming the layer includes one or all of chemical vapor deposition, the hollow cathode effect, and high power DC pulsing.

### CROSS-REFERENCE TO RELATED APPLICATION

This application claims priority from U.S. provisional application Ser. No. 60/993,567, filed Sep. 12, 2007.

### TECHNICAL FIELD

The present invention relates generally to solar cells and more particularly to methods and apparatus for fabricating solar cells.

### BACKGROUND ART

Silicon is the most commonly used component for forming a photovoltaically active material, since silicon is abundant, inexpensive, and environmentally responsible. Of the various forms of silicon, hydrogenated amorphous silicon (a-Si:H) film deposited by plasma enhanced chemical vapor deposition (PECVD) is the least expensive used in fabricating solar cells. However, the current state of the art solar cell manufacturing technology employs large inexpensive PECVD machines.

Despite the large capital equipment requirements, an a-Si:H layer that is formed using conventional processing by material properties which limit photovoltaic efficiency to approximately 10%, as compared to the 30% or 40% level which would be achieved with ideal material properties. “Photovoltaic efficiency” is defined as a ratio of the electric power produced by a photovoltaic device to the power of the light incident on the device. Despite the low photovoltaic efficiency, solar cell production technology has reached a price-point threshold that triggers large market response. The goal is to decrease the cost per Watt of power that is generated, as compared to fossil fuel, hydroelectric and nuclear alternatives.

Two factors which are significant in determining the photovoltaic efficiency upper limit are the absorptivity and the carrier lifetime properties of the layer. Solar absorptivity is the fraction of the incoming solar energy that is absorbed by the layer. Since absorbed photons generate the charge carriers (free electrons or holes), increasing the absorptivity of a particular material is likely to increase the generation of charge carriers. The carrier lifetime is the average time a charge carrier exists before recombination.

In a conventional a-Si:H structure, a disordered silicon atom arrangement enables a higher absorptivity than would be possible with crystalline silicon. It is possible that approximately one hundred times more light is absorbed per unit thickness by the a-Si:H structure. However, while absorptivity is an important requirement for low cost solar cells, conventional atomic disorder also result in a high rate of recombination of photo-generated carriers. That is, amorphous silicon exhibits a lower carrier lifetime than does crystalline silicon. In disordered a-Si:H material, a high fraction of the photo-generated electrons and holes recombine before drifting to electrodes, thereby preventing their contribution to photo voltage or photo current. The hydrogenation of the a-Si:H structure plays a role of dramatically reducing the density of recombination traps, but high recombination rates remain as a major leveling factor for achieving a high photovoltaic efficiency. Crystalline silicon does not have the same problem, since it exhibits the higher carrier lifetime, but thicker photovoltaically active layers are required in order to compensation for the lower absorptivity of crystalline. This is significant, since the increase in layer thickness increases the overall expense of a solar cell.

### SUMMARY OF THE INVENTION

In accordance with the invention, at least one photovoltaically active layer of a solar cell is formed as a “hybrid” of regions in which first regions exhibit high absorptivity and second regions have a longer range order in a direction generally perpendicular to the major surfaces of the layer, thereby exhibiting a longer carrier lifetime than the first regions. The photovoltaically active layer is a film which is homogenous in a lateral direction (i.e., parallel to the major surfaces) with respect to film constituents, but is non-homogenous with respect to photovoltaic properties. The high absorptivity exhibited by the first regions ensures generation of sufficient charge carriers for a given layer thickness, while a medium or long-range order (in either atomic positions or stoichiometry) enables high mobility channels to be formed within and around the first regions.

Conventional approaches to fabricating a silicon-based photovoltaic structure encounter a tradeoff between absorptivity and carrier lifetime, since amorphous silicon more readily absorbs incident photons to generate charge carriers, but crystalline silicon is superior with respect to the carrier lifetime. Using the “hybrid approach” circumvents this tradeoff. Nano-layered transitions from amorphous to nanocrystalline define the high absorptivity first regions adjacent to the high carrier lifetime second regions. While both regions are compatible with generating the charge carriers and both regions enable carrier mobility, the second regions provide medium or long range order in the vertical direction (normal to the major surfaces), so as to achieve sufficient carrier lifetime to allow a greater percentage of the photo generated electrons and holes to reach electrodes on the major surfaces.

While the “hybrid approach” is described primarily with respect to silicon-based layers, the approach may be used in other applications. A way of example, the photovoltaically active layer may be based upon Ge, GaAs, SiGe or other semiconductor materials. For the silicon-based structure, the first regions are hydrogenated amorphous silicon (a-Si:H), while the second regions are hydrogenated crystalline silicon (c-Si:H). However, the benefits of the invention apply to more complex structures, such as multi-junction (e.g., triple junction) structures in which material constituents are charged through a sequence of layers/films in order to provide multiple band gases. Then, different portions of the solar spectrum are converted at different junctions, thereby increasing overall efficiency.

In accordance with a method of forming the photovoltaically active layer, the “vertically ordered” silicon in the second regions may be formed by providing sufficient energy to a growing chemical vapor deposition (CVD) surface so as to give the silicon atoms mobility to move energetically favored areas, but with less energy than would result in the silicon atoms being removed from their positions within the second regions. The short range order in the first regions is energetically favored when there is an incident high energy pulse of silicon reactive species during fabrication, instantaneously forming amorphous material. After reaching the growing surface, the silicon atoms of the amorphous layer tend to rearrange into energetically preferred locations, with preference being given to locations which have already developed a “template” of amorphous and nanocrystalline locations. The formation of the original “template” may be controllable, but a randomization in the locations of the second regions at the onset of the layer deposition is within the scope of the invention. As will be readily understood by a person skilled in the art, “islands” of nanocrystallization will occur during the CVD processing. The process parameters are then controlled to continue the location of the nanocrystallization as the layer is grown. A high mobility channel through the layer may be continuous throughout the thickness or may be aligned but separated regions exhibiting medium to long range order.

The process that is well suited for forming the photovoltaically layer in accordance with the invention employs the hollow cathode effect and high power DC pulsing. The pulse duration is a particularly important factor. Longer pulses increase the amount of time for the silicon atoms to establish their energetically preferred locations. Nevertheless, the time between two high powered DC pulses is not less than the duration of each pulse. An example of a PIN solar cell junction formed using this method is as follows: a hollow cathode chamber containing the solar cell substrate (e.g., a stainless steel foil) is heated in hydrogen at a 50% duty cycle. A p-type junction may be formed using silane and 2% diaborane (or other p-type dopant), followed by an intrinsic silicon layer (typically the layer of focus with respect to the present invention). Two frequencies can be used for power application to the plasma, with the higher frequency pulsing preferably being at 25 kHz and a 50% duty cycle. The lower frequency “burst” at 25 Hz can be run (but may be deleted in some embodiments) at a 10% duty cycle for a total duty cycle of 5%. High current per pulse is used for the higher frequency pulsing, such as a current in the range of 25 mA/2.54 cm² to 100 mA/2.54 cm², (e.g., a 25 kHz pulse at 60 mA/2.54 cm²). Following this, the n-type layer may be formed using silane and 2% phosphine (or other n-type dopant) in hydrogen. Preferably, the pulse duration is within the range of 5% to 50% of the cycle. As one possibility, 1,000 volt pulses (20 W/cm²) have a 10 microsecond “on” time and 90 microsecond “off” time, yielding a morphology which has the correct regime, according to TEM evaluation (transmission electron microscopy).

The “hollow cathode effect” as used herein. In case a large increase in current as compared to convention plasma glow. The increase is due to the “oscillation motion” of fast (hot, accelerated) electrons between opposite space charge sheaths, which enhances the excitation and oscillation rates in the plasma several times higher than the conventional glow discharge. Because this electron pendulum motion is related to the mean free path of the fast electrons, there is a relationship of the hollow cathode effect to pressure within the hollow cathode and the spacing between the two or more electrodes. That is, a hollow cathode with a small spacing will operate at a higher pressure than a hollow cathode with a larger spacing.

While the fabrication of one or more photovoltaically active layer in accordance with the invention may take place within a tube, the end product need not be tubular. For applications in which the layer is formed within a cylindrical workpiece, the workpiece may be cut into sections which then are used to generate solar energy. Arcs of 120 degrees to 180 degrees substantially increase the collected solar power when exposed diffused light, such as in cloudy or hazy conditions.

In another embodiment, the photovoltaically active layer is formed on a substrate that is progressed through an area in which the proper deposition conditions are established. For example, a flexible substrate may be progressed through one or more tubes in which a hollow cathode effect is established. The substrate may temporarily or permanently cover the wall of the tube. Alternatively, the substrate may cover only a portion of the tube wall, such as a spiraling substrate that is progressed through the tube.

### BRIEF DESCRIPTION OF THE DRAWINGS

FIG. 1 is a photograph of a-Si:H layer on a steel substrate, such as may be formed using known techniques.

FIG. 2 is a TEM of a-Si:H deposited in accordance with the invention.

FIG. 3 is an illustration of a nanolayer transition from “granular” to “amorphous” in accordance with the invention.

FIGS. 4-7 conceptually illustrate “hybrid” layers having first and second regions in accordance with the invention.

FIGS. 8-12 are illustrations of alternative cylindrical chambers for depositing a hybrid layer, such as one shown in FIG. 4.

FIG. 13 is a conceptual illustration of an alternative use of the formation of nanocrystalline columns in a solar cell.

### DETAILED DESCRIPTION

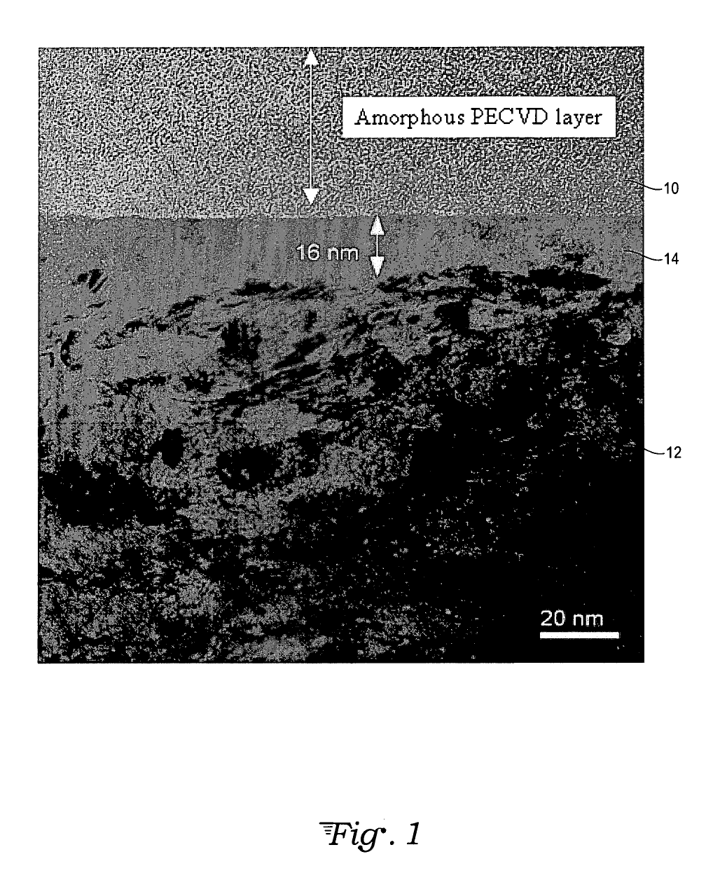

FIG. 1 shows an a-Si:H layer 10 formed on a steel substrate 12. The a-Si:H layer was formed using PECVD techniques. Additionally, the deposition of this layer occurred after establishing a hollow cathode effect within a deposition chamber, such as described in U.S. Pat. No. 7,300,684 to Boardman et al. and U.S. Patent Publication No. 2008/002994 to Tudhope et al., both of which are assigned to the assignee of the present invention. In relating the description of these two patent documents to the formation shown in FIG. 1, the steel substrate 12 is a workpiece in which the hollow cathode effect is established. Since the electron mean-free path is related to the inner diameter of the workpiece, the proper pressure setting will cause high energy electrons to oscillate between electron walls and an increase in ionizing collisions will occur. In establishing this condition, pressure must be decreased as the diameter of the workpiece is increased. As one possibility, a 25 millimeter diameter pipe will generate a hollow cathode plasma at a pressure of approximately 200 mTorr, while an 101.6 millimeter diameter workpiece will generate a hollow cathode plasma at a pressure of approximately 50 mTorr. However, these examples are provided only for purposes of illustration.

In FIG. 1, the amorphizing plasma treatment is performed with sufficient energy to effect grains of the steel substrate 12 to a depth of 16 nm, as shown at area 14. In this area, the grain size has been decreased. The illustrated structure may be formed using an argon pulse DC plasma with an 80-90% duty cycle for amorphizing, followed by a pulse DC PECVD to provide the layer 10.

In a conventional a-Si:H structure, a disordered silicon atom arrangement enables a higher absorptivity than would be possible with crystalline silicon. However, as previously noted, conventional atomic disorder also results in a high rate of recombination of photo generated carriers. The hydrogen is used for dramatically reducing the density of recombination traps, but high recombination rates remain a major limiting factor for achieving high output energy efficiency in silicon-based solar cells. Crystalline silicon does not have the same problem, but thicker photovoltaically active layers are required because of the lower absorptivity of crystalline silicon. Increases in thickness significantly increase the overall expense.

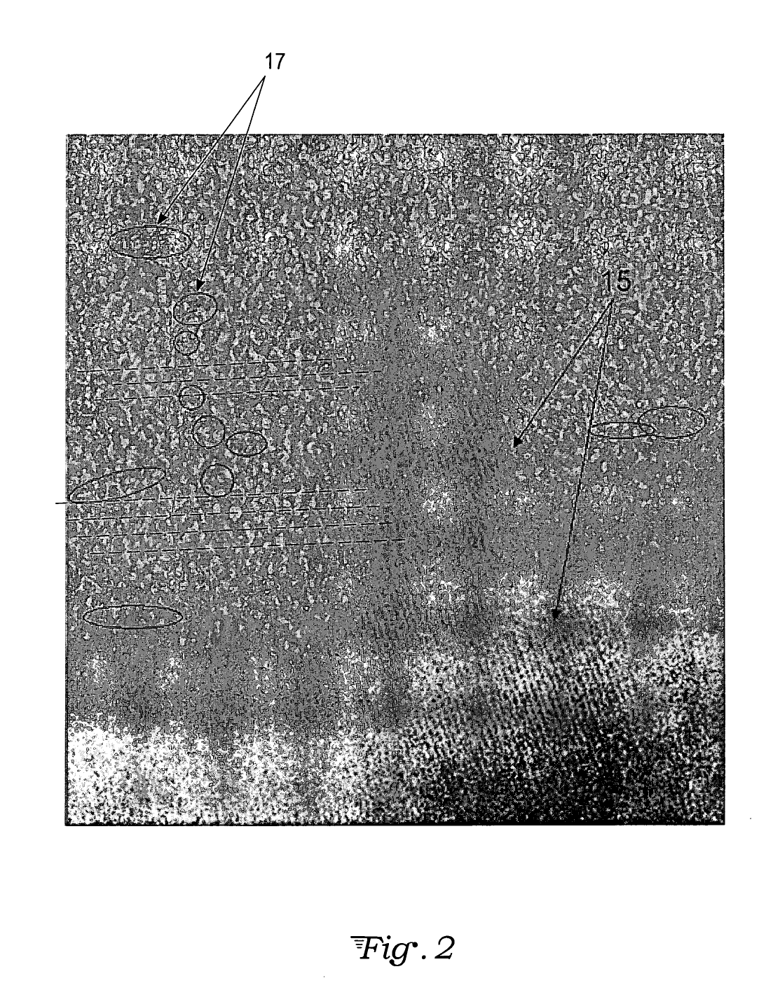

FIG. 2 is a TEM illustration of a-Si:H deposited on a stainless steel workpiece in accordance with the invention. Darker areas 15 at the lower portion of the illustration and in the center upwardly extending portion represent the interface between the materials. Above the stainless steel are relatively disordered a-Si:H regions of short-range order. These regions of short-range order are identified by dashed circles and ovals 17. Briefly, the deposition process conditions included SiH₄+H₂ PECVD, with less than 15% duty cycle of 20 W/cm² pulses at 300 degrees centigrade.

In the acquisition of the TEM of FIG. 2, patterns of order in the a-Si:H modulated the electron beam as it passed through the sample thickness nominally 1,000 angstroms. In the illustration, parallel dashed lines at 5 micron and 1.7 micron intervals are indicated for purposes of reference. Insipient short range order is associated with favorable photovoltaic properties, as compared to purely random morphology.

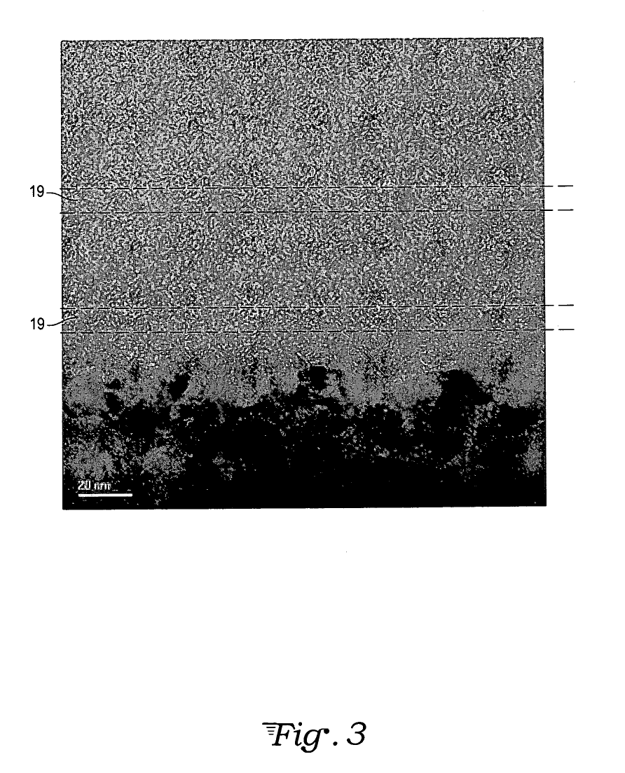

Variable high power pulsing enables deposition of nanolayered transitions from amorphous to nanosilicon, with tunable short range order. This is illustrated in FIG. 3. Parallel dashed lines are included to show the nanolayer transitions from “granular” to “amorphous”. The regions 19 between the closely adjacent parallel-lines represent two areas that are primarily homogenous a-Si:H, with granular features of approximately 2-4 nm. Above each area 19 is an area of a-Si:H that includes such granular features. PECVD plasma conditions resulted in the morphological variations. The chemistry was 1% SiH₄ in argon and H₂, with alternating “on bursts” and “off intervals.” The parallel dashed lines shown in the figure represent intervals of 9 nanometers.

The ability to fabricate nanolayer transitions changing the degree of morphological order (either atomic positions or stoichiometry) is an important process capability in optimizing the a-Si:H photovoltaic properties. As background, researchers at the Lawrence Berkeley National Laboratory have identified the use of small-size material domains (nanometer range) for absorbing more photon energy than would be possible for homogenous semiconductor material. Semiconductor nanocrystal-based cellular imaging is described in U.S. Patent Publication No. 2003/0113709 to Alivisatos et al. Within the patent document, a “quantum dot” is defined as a semiconductor nanocrystal, which is a protein-sized crystal of organic semiconductor nanocrystals, initially developed for optically electronic applications. The concept is to create a special type of structure that enables incoming photons to release more than one set of electron-hole pairs. This special structure is a small bounded domain with nanometer dimensions. The primary interaction is between a photon and a small domain. When the photon has sufficient energy for more than one electron-hole pair, a second electron-hole pair is more likely to be formed if the photon energy is confined to the quantum dot rather than being dissipated in a surrounding material. The process provides primary homogenous a-Si:H produced with high power transient DC pulse verse, a 5-50 W/cm² DC with a peak voltage of 1,000 volts used to trigger the discharge.

In comparison to the processing for providing the “quantum dots”, the present invention relates to photovoltaically active layers arising from unique energy distribution of plasma species present in a hollow cathode discharge with high power pulsed DC operation. A stacked nanolayer 3-dimensional quantum well array may be defined, with grain boundaries (precipitates and defects) as lateral quantum well boundaries and with nanolayer edges as “top” and “bottom” quantum well boundaries. High efficiency is enabled by multiple electrons being associated with a high energy photons.

While FIG. 3 illustrates nanolayered transitions in the horizontal direction, the preferred embodiment of the invention involves nanolayering in the vertical direction. As used herein, the vertical dimension is in the growth direction of the layer. Thus, following formation of the layer, the major surfaces are at opposite ends of the layer thickness.

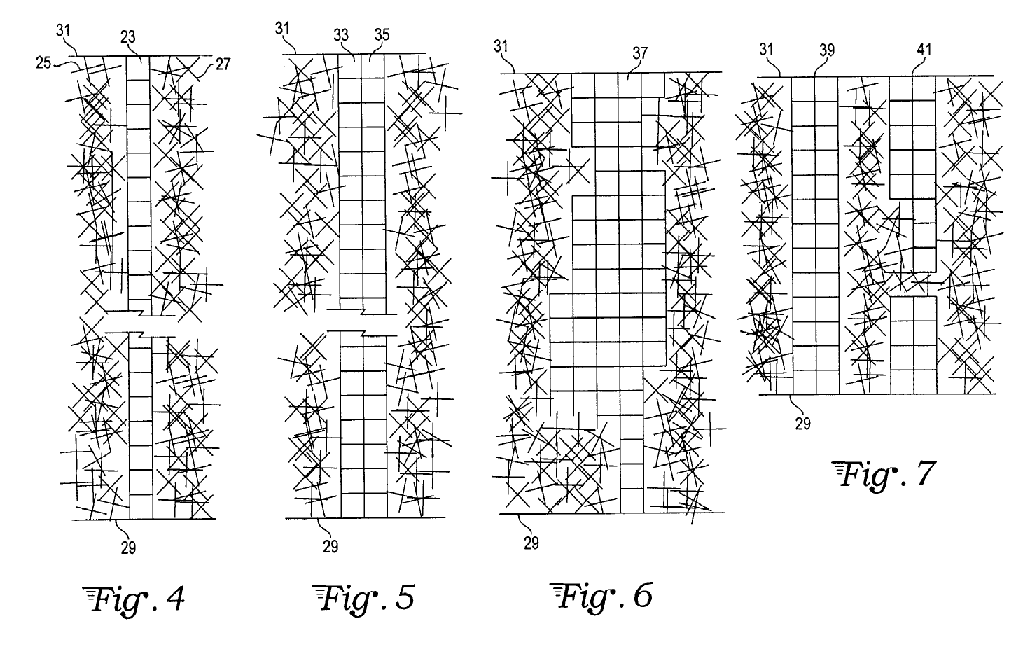

FIGS. 4, 5, 6, and 7 are conceptual illustrations of four embodiments of the invention. In each illustration, a small segment of photovoltaically active material is shown as including a “hybrid” of regions in which first regions exhibit high absorptivity and second regions have a medium or long range order in a direction generally perpendicular to the major surfaces of the layer. That is, the second regions have a lattice-like arrangement of atoms, thereby providing a longer carrier lifetime than the first regions. While each layer is a film that is homogenous with respect to constituents of the film, the photovoltaic properties are non-homogenous. The high absorptivity of the first regions promotes absorptivity of charge carriers, while the medium or long range order of the second regions promotes mobility of the charge carriers.

In FIG. 4, the lattice-like second region 23 is between a pair of amorphous first regions 25 and 27. The second region is a single column of crystalline silicon cells. Each cell may have a size of 5.3 angstroms, the smallest unit of the ordered silicon lattice. In FIG. 4, the second region extends throughout the thickness of the photovoltaically active layer, from a lower major surface 29 to an upper major surface 31. Thus, the number of cells which comprises the second region will depend upon the thickness of the layer. For example, there may be 2,500 cells.

FIG. 5 illustrates an embodiment in which the second section is formed of two columns 33 and 35 of medium to long range order. As in FIG. 4, only a portion of the thickness is represented, as indicated by broken lines towards the center of the layer. Relative to the single-cell column of FIG. 4, the embodiment shown in FIG. 5 provides enhanced charge carrier mobility.

In FIG. 6, the width of the second section varies through the thickness of the photovoltaically active layer. The variation is shown as being a maximum of five crystalline silicon cells and a minimum of one cell. Mobility will change depending upon the lateral dimension of the second region but will remain continuously greater than charge carrier mobility within the amorphous first regions.

In the embodiment of FIG. 7, two lattice-like regions 39 and 41 are shown. The lattice-like region 41 is not continuous through its vertical extension. That is, there is a discontinuity in the ordering of cells. Often, such discontinuities occur, but the resulting structure remains within the scope of the present invention, since the process parameters in the fabrication are established such that induced ordering along the vertical dimension is implemented to provide second regions in which high mobility paths are provided to at least one major surface 29 and 31 in order to increase efficiency in the conduction of charge carriers to a major surface. Thus, an electrode on the major surface will receive a higher percentage of charge carriers formed within the first and second regions.

From the foregoing it can be seen that the present invention departs from conventional silicon-based photovoltaically active layers, since the hybrid structure is defined. The first areas exhibit high absorptivity, while the second areas exhibit high carrier mobility in the vertical dimension. In the method of forming the photovoltaically active layer, the vertically ordered silicon in the second regions may be formed by providing sufficient energy to a growing chemical vapor deposition surface so as to give the silicon atoms sufficient mobility to move to energetically favored areas. However, the applied energy should be less than that that would result in the silicon atoms being removed from their positions within the second regions. The short range order in the first regions is energetically favored when there is an incident high energy pulse of silicon reactive species during fabrication, instantaneously forming amorphous material. During initial growth, “islands” of nanocrystallization will occur. These “islands” create a “template” of amorphous and nanocrystalline locations. The process parameters are then such that this template is maintained throughout the growth process.

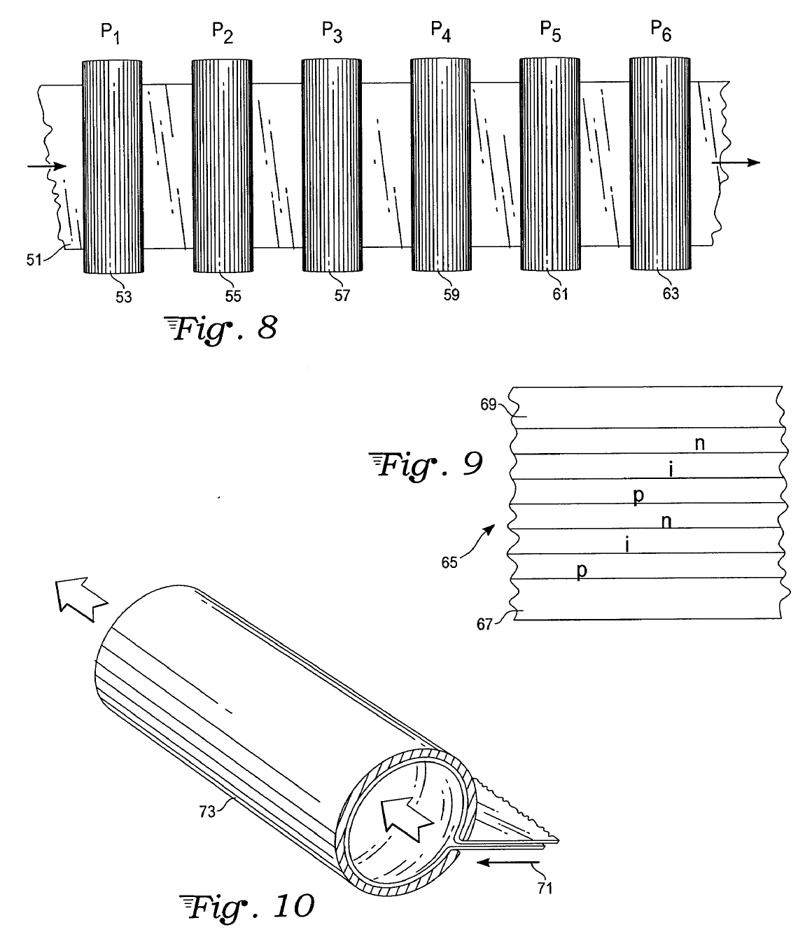

In forming a solar cell of which the photovoltaically active layer is a component, a hollow cathode chamber is used to establish the hollow cathode effect. In some applications of the invention, the solar cell layers are formed directly on the chamber walls. For example, a cylindrical stainless steel substrate may be used as the substrate, whereafter the substrate may be cut into 90 degree or 180 degree sections for end use. Alternatively, a stainless steel foil may be passed through one or more chambers, as will be described with reference to FIG. 8. A continuous web of substrate material 51 is passed through a number of tube processors 53, 55, 57, 59, 61, and 63. The number of tube processors is not critical to the invention. Each processor is preferably cylindrical and includes a pair of slots for insertion and removal of the substrate, as well as a mechanism for causing the substrate to follow the contour of the inner walls of the substrate. However, there are applications in which following a contour is not significant.

The first process chamber 53 may be dedicated to cleaning the substrate, rather than forming a layer. A stainless steel foil may be cleaned in hydrogen at a duty cycle of approximately 50%. The following process chambers may be used to deposit the layers which form the solar cell. Thus, process chambers 55, 57, and 59 may sequentially deposit an p-type hydrogenated silicon layer, the process chamber 57 may deposit an i-type hydrogenated silicon layer, while the following process chamber 59 may deposit a n-type hydrogenated silicon layer. The three-layer sequencing may be repeated. FIG. 9 shows a layer stack 65 that includes two such sequences of layers. The layers are formed on stainless steel foil 67. A transparent conducting oxide (TCO) 69 is formed on the top.

The thicknesses of the various layers deposited within the tube processors 53-63 of FIG. 8 are consistent with conventional practices. The significant difference from conventionality is that at least one of the layers is formed to include both the first regions that exhibit high absorptivity and the second regions that exhibit high mobility. Typically, the TCO 69 is significantly thicker than the other layers. In order to standardize the speed of the substrate 51 through the various chambers, the TCO layer may be formed using a number of the tube processors, with each processor contributing a portion of the layer.

By way of example, a p-type layer may be formed using silane and 2% diaborlane. Following formation of the p-type layer, an intrinsic silicon layer is formed.

In order to establish a hollow cathode effect within the different tube processors 53-63, the conductive processors are biased. Two frequencies can be used for power application to the plasma within a processor. The higher frequency is a pulsing that preferably occurs at 25 kHz, with a 50% duty cycle. The lower frequency “burst” occurs at 25 Hz and may have a duty cycle of 10%. Thus, the combined pulsing has a duty cycle of 5%. Each pulse of the higher frequency should have a high current, such a current in the range of 25 mA/2.54 cm² to 100 mA/2.54 cm² (for example, a 25 kHz pulse at 60 mA/2.5 cm²).

FIG. 10 shows an alternatively roll-to-roll processing configuration. Rather than having an opening at both sides of a cylindrical processing chamber, the processing chamber 73 of FIG. 10 includes a single opening. As indicated by arrow 71, a feed portion of a substrate material enters the chamber. Pressure is applied in order to cause the substrate material to follow the contour of the chamber and to establish the hollow cathode effect. A film is formed on the substrate material as it moves through the chamber. Then, the coated material is removed and progressed to the next chamber, not shown.

FIGS. 11 and 12 illustrate alternative embodiments in which a roll 75 of substrate material is cause to spiral through the cylindrical chambers 77 and 79. Anodes are placed at both ends of the cylindrical chambers and a precursor is channeled through the chambers, with the required pressure being applied in order to establish the hollow cathode effect.

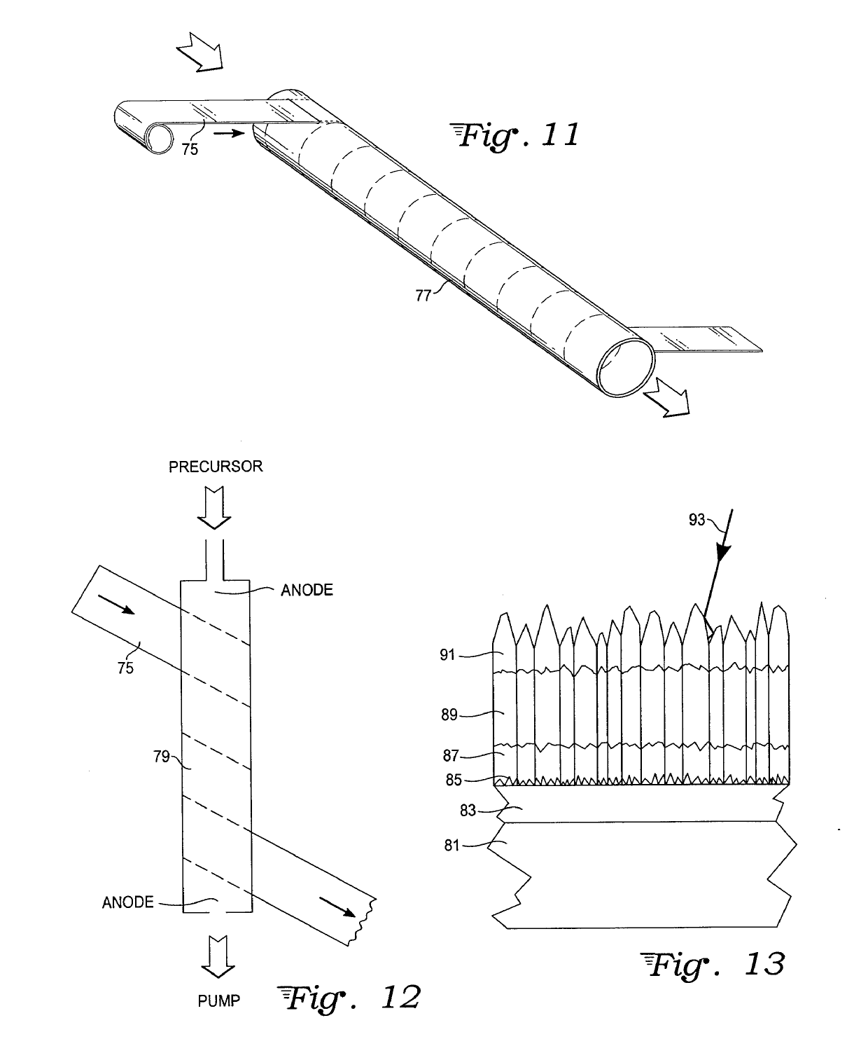

FIG. 13 is a conceptual illustration of another application of the above-identified techniques for forming nanocrystalline “columns.” One known technique for increasing the efficiency of a solar cell is to texture a substrate or a reflective material on a substrate in order to cause reflection of photons which might otherwise be incident to the solar cell but without generating charge carriers. In FIG. 13, texturing occurs within one of the junction layers, rather than in the substrate or the coating that supports the solar cell layers.

In the illustrated embodiment, the substrate 81 may be a stainless steel foil. A zinc oxide layer 83 is formed on the substrate. Then, an amorphous silicon 85 is provided. FIG. 13 will be described with reference to a silicon-based solar cell, but the approach may be used with other materials. Above the amorphous silicon are the p-type silicon layer 87, the intrinsic silicon layer 89 and the n silicon layer 91 that cooperate in the generation of a photo current.

A significant difference between the structure of claim 13 and the conventional approach of forming a solar cell is that nanocrystalline silicon columns are formed using the techniques which are described above. Thus, high power DC pulsing is applied and the hollow cathode effect is established in order to provide layer texturing as shown in the n silicon layer 91. Additional layers are then provided. For example, the sequence of the three layers 87, 89, and 90 may be repeated as described with reference to FIG. 9.

In FIG. 13, the travel of a single photon 93 is represented in order to illustrate the benefit of the incorporation of nanocrystalline silicon columns. Instead of the photon following a straight path, the nanocrystalline columns induce deflections. In the same manner as the deflection that is induced as a consequence of texturing of a substrate or a coating on the substrate, the deflection of photons by the nanocrystalline columns increases the overall efficiency of the solar cell.

What is claimed is:

1. A photovoltaically active layer comprising:
a single film of material which is responsive to incoming light to generate charge carriers, said film having first and second major surfaces and having first and second regions, in a lateral direction that is parallel to said first and second major surfaces said film being homogenous with respect to constituents of said film but being non-homogenous with respect to photovoltaic properties, said first regions being amorphous, said second regions having longer range order than said first regions and extending generally perpendicular to said major surfaces, said first regions thereby exhibiting a higher carrier generation rate than said second regions while said second regions exhibit a greater carrier lifetime than said first regions.

2. The photovoltaically active layer of claim 1 wherein said first and second regions are hydrogenated silicon (Si:H).

3. The photovoltaically active layer of claim 1 wherein said second regions are generally parallel lattice arrangements of particles.

4. The photovoltaically active layer of claim 3 wherein said particles include silicon.

5. The photovoltaically active layer of claim 4 wherein said first regions include amorphous silicon and said second regions include nanocrystalline silicon, said first and second regions being within a unitary deposition of said material.

6. The photovoltaically active layer of claim 1 wherein a plurality of said second regions are spaced apart but aligned along a path between said first and second major surfaces, such that said path exhibits a high carrier mobility.

7. A method of forming a photovoltaically active layer comprising:
forming a plasma within a deposition environment, said plasma including material to be deposited along a surface; and
establishing deposition conditions such that said material is deposited as amorphous first regions and nanocrystalline second regions that have a lattice arrangement in general alignment with deposition growth of said photovoltaically active layer, wherein establishing said deposition conditions includes applying a pulsed bias so as to provide mobility to atoms of said material into locations that maintain said first and second regions as said deposition growth occurs.

8. The method of claim 7 wherein establishing said deposition conditions includes controlling both pressure and said pulsed bias to establish a hollow cathode effect.

9. The method of claim 8 wherein forming said plasma and establishing said deposition conditions provide chemical vapor deposition (CVD) of said material.

10. The method of claim 7 wherein said material to be deposited includes silicon, said first regions being amorphous silicon and said second regions being silicon having longer range order than said first regions, said second regions extending to major surfaces of said layer upon completion of said deposition growth.

11. The method of claim 7 wherein applying said pulsed bias includes providing DC pulses in which a time during which a voltage is applied is significantly shorter than a time during which no voltage is applied.

12. The method of claim 7 wherein said deposition environment is a chamber defined by a tube, said material being deposited along an interior diameter of said tube.

13. The method of claim 7 wherein said deposition environment is a chamber defined by a tube, said method further comprising progressing a substrate through said tube, said material being deposited on said substrate.

14. The method of claim 7 wherein applying said pulsed bins includes employing high power DC pulses.

15. The method of claim 14 wherein employing said high power DC pulses applies a power per pulse of at least 20 W/cm².

16. The method of claim 15 wherein application of said high power DC pulses has a duty cycle of less than fifty percent.

17. A method of forming a solar cell having a sequence of layers to generate photo current in response to incident light, said method comprising:
applying chemical vapor deposition techniques in forming said sequence of layers, including forming at least one layer in said sequence by:
a) establishing a hollow cathode effect driving deposition of said at least one layer; and
b) applying DC pulses such that said at least one layer is grown as a silicon-based layer having defined amorphous regions extending perpendicular to a growth direction and further having defined second regions extending parallel to said growth, said second regions establishing higher charge carrier lifetime regions relative to said amorphous regions.

18. The method of claim 14 wherein applying said DC pulses includes controlling a pulse amplitude and a pulse duration to provide mobility to silicon atoms of said silicon-based layer such that said silicon atoms reach energetically formed locations which maintain positions of said amorphous and second regions during growth of said silicon-based layer.

19. The method of claim 14 wherein establishing said hollow cathode effect and applying said DC pulses are utilized during growth of a plurality of silicon-based layers of said sequence.

20. The method of claim 14 wherein each said layer of said sequence of layers is applied using plasma enhanced chemical vapor deposition.
